(19) United States
(12) Patent Application Publication
(10) Pub. No.: US 2024/0332899 A1
(43) Pub. Date: Oct. 3, 2024

(54) Cleaved Coupled Cavity AMQ Diode Configuration for Wide-Range Tunable Lasers

(71) Applicant: KING FAISAL UNIVERSITY, Al-Ahsa (SA)

(72) Inventor: Hesham M. ENSHASY, Al-Ahsa (SA)

(21) Appl. No.: 18/191,966

(22) Filed: Mar. 29, 2023

(51) Int. Cl. H01S 5/14; H01S 5/0625; H01S 5/10; H01S 5/34

(52) U.S. Cl. CPC H01S 5/142; H01S 5/06255; H01S 5/1082; H01S 5/34

(57) ABSTRACT

A continuously electronically tunable semiconductor laser has a lasing section, and first and second control sections separated from the lasing section by air gaps in a longitudinal arrangement. The longitudinal arrangement positions the lasing section between the two control sections, with the longitudinal arrangement corresponding to a lasing direction of the lasing section. The arrangement places longitudinal modes of the semiconductor laser in common with the longitudinal arrangement of the sections. Current is provided to each of the first and second control sections and the lasing section. Tuning is achieved by varying the current provided to at least one of the first control section, the second control section and the lasing section.

### BACKGROUND

### Technical Field

The disclosed technology relates to a tunable cleaved coupled cavity (C3) laser diode using an uncoated Fabry-Pérot resonator.

### Background Art

Many industries in recent decades adapted tunable lasers by selecting single modes in the 1-2 μm infrared region. Significant interest for these types of lasers developed in many applications such as medical, optical communication, military and environmental engineering. Two methods can achieve tunable semiconductor lasers:
mechanically tunable lasers, which are sub grouped into well-known external cavity diode lasers and micro-electro-mechanical systems (MEMS) tunable diode lasers; and
electronically tunable lasers.

The mechanical tuning scheme includes a diode laser and one or more optical elements forming an external cavity. Most commonly, a lens and a wavelength dispersive element like a diffraction grating are used. The lens-grating combination can also be replaced by a Diffractive Optical Element (DOE). A DOE is more advantageous than a lens-grating combination because it replaces the angular rotation required for a grating by a simple linear motion and also eliminates the requirement of a lens. This creates the possibility of monolithic fabrication of a DOE external cavity tunable laser.

External Cavity Diode Lasers (ECDL) have been proposed, which are built on ECDL configurations that were extensively studied and developed since the 1960s. ECDL has also been combined with micro-fabrication techniques of 3D structures based on MEMS technology.

MEMS tunable diode lasers are similar to the external cavity tunable diode lasers except the optical elements in this case are miniature in size. For the external cavity or MEMS tunable laser, a fraction of the output beam is fed back into the active cavity by the optical elements changing the phase and amplitude balance of light inside the cavity.

For electronic tuning, the optical cavity length of the laser is varied by changing the effective index (neff) of the laser. The neff is changed either by the application of a varying electrical field or by changing the injection current. Although the index change with the application of an electric field enables high speed tuning, the index shift is small, and offers limited tuning range. Index change by changing injection carriers is the most frequent method used in wavelength tuning. Carriers injected into the waveguide by an external current source can reduce the effective index. The refractive index change due to the injected carriers into a semiconductor is due to the effects of free carrier absorption, band filling, and band-gap shrinkage. Joule heating due to the injected current also causes a decrease of the bandgap and hence changes the refractive index. In addition, an injected carrier density also causes a refractive index change at the peak gain energy because of the strong asymmetric shape of the semiconductor gain curves and can be calculated with the Kramers-Kronig dispersion relations.

Distributed feedback (DFB) lasers, distributed Bragg grating (DBR) lasers and coupled cavity lasers employ electronic tuning mechanisms. Some of the first electronic tunable lasers were multi section DFB based lasers with a complicated operation scheme having a very modest tuning range of ˜3 nm. Thermally controlled DFB tunable lasers were also proposed but they offered 3-4 nm tuning range for a 30-40° C. temperature variation. To increase the tuning range, vendors often use a selective array of DFB lasers.

The continuous tuning range of a diode laser is limited by mode hops, which occur since the cavity length cannot be tuned synchronously with the gain profile, and where a resonator is usually formed by its end facets. For a vast majority of commercially available diode lasers, some sections of the spectral range covered by the gain profile are not accessible because of the mode hops issue.

Continuous tuning, i.e., mode hop free tuning, has been achieved with tunable lasers in an external cavity configuration, in which the wavelength tuning is obtained by rotating an optical element about a remote pivot. Due to the bulky optical elements, the speed of tuning is very slow compared to electronic tuning. For MEMS wide tunable lasers, achieving desired tuning speeds and tuning ranges can be challenging. The speed of single mode tuning is determined by the dimensions of the mechanical laser device. The upper limit of tuning speed of a MEMS wide tunable laser is directly related to the material stiffness and inversely related to the mass of the mechanical structure. Since the stiffness is a material property and it is constant under normal conditions, then the mass of the mechanical structure needs to be reduced to increase the speed of tuning. One example of such thickness reduction is decreasing the thickness of the micro actuator. By doing so a large increase in resonance frequency can be reached. Recently, a high speed tunable MEMS Vertical Cavity Surface Emitting Laser (VCSEL) structure was reported with a tuning speed of ˜16 MHz however the tuning range was about ˜3 nm. Tunable Fabry-Perot edge emitting MEMS diode lasers are usually available from multiple laser sources with a maximum tuning range of ˜40 nm; however, scanning speeds can be slow.

The use of antireflection coatings on the diode facets generally helps with continuous tuning. Several approaches have demonstrated that these external cavity diode lasers are capable of mode hop free continuous tuning because of the ability of controlling cavity length independent of the diode current. Since a larger length of the external cavity implies smaller spacing between the cavity modes, mode selective elements such as gratings or etalons are used.

All of these methods for continuous tuning require a synchronous tuning of the active cavity length and mode selectors. This requirement complicates the whole tuning operation.

### SUMMARY

A continuously electronically tunable semiconductor laser is operated with a lasing section, and first and second control sections separated from the lasing section by air gaps in a longitudinal arrangement. The longitudinal arrangement positions the lasing section between the two control sections, with the longitudinal arrangement corresponding to a lasing direction of the lasing section, thereby placing longitudinal modes of the semiconductor laser in common with the longitudinal arrangement of the sections. Current is provided to each of the first and second control sections and the lasing section. Tuning is achieved by varying the current provided to at least one of the first control section, the second control section and the lasing section.

### BRIEF DESCRIPTION OF THE DRAWINGS

FIG. 1 is a schematic diagram showing a cleaved coupled cavity three-section laser device.

FIG. 2 is a graphic depiction showing net gain coefficient found from a spectrum measured by an optical spectrum analyzer (OSA) at different current injection levels.

FIG. 3 is a graphic depiction showing an OSA-measured spectrum for a continuous tuning method.

FIG. 4 is a graphic depiction showing tuning of a single mode.

FIG. 5 is a graphic depiction showing continuous tuning of a lasing device.

FIG. 6 is a graphic depiction showing the effect of changing both currents on the output of a C3 laser.

FIG. 7 is a graphic depiction showing the spectrum range of sample wafers that can be obtained by changing applied current.

### DETAILED DESCRIPTION

The present disclosure provides a simple technique for continuous tuning of lasers, using uncoated diode lasers and employing an electronic tuning mechanism. This results in much faster tuning compared to the external cavity or MEMS tunable lasers. For the external cavity or MEMS tunable laser, a fraction of the output beam is fed back into the active cavity by the optical elements changing the phase and amplitude balance of light inside the cavity. Wavelengths with the highest single pass gain-reflectivity (RG) product, when fed back into the cavity, will be enhanced further and become the enforced mode of the system.

A broadly tunable two-section cleaved coupled cavity (C3) laser is disclosed. C3 lasers are very capable single longitudinal mode sources. The coupled cavity structure suppresses other longitudinal modes very effectively; however, there are multiple “single modes” on which a C3 laser can operate.

The disclosed simpler method is to stitch together overlapping sections to obtain continuous coverage of a spectral region. Although stitching can be used, a gap in the spectral range will arise due to some modes falling from the range due to current limitations in both sections of the C3 laser. As a solution to this problem three cavity sections are employed in the laser lasing section as a lasing section and two control sections.

Coupled cavity devices are obtained by creating multiple laser cavities on a single substrate. The multiple cavities are obtained by cleaving or by etching through the active region. Coupled cavity devices are tuned over the modes by adjusting current to the sections that form the coupled cavities. Coupled cavity lasers are wavelength agile laser sources. The wavelength can be switched rapidly with a change in the injection current.

In one non-limiting example, a C3 laser diode configuration is used as a technique for continuous tuning of broadly tunable 1400-1600 nm type laser diode devices. An uncoated Fabry-Pérot resonator with a two or three section current tuning mechanism provides a wide-range tunable laser of this type. This wavelength switchable semiconductor laser uses three coupled Fabry-Perot cavities. The result is a continuous wavelength tuning laser device that uses one long optically active section and two short optically passive sections placed at each end of the long section. The configuration allows the laser device to be continuously tuned over 100 nm without requiring the use of an electrical feedback circuit to stabilize the wavelength to which the laser device is switched.

The disclosed C3 laser diode uses two section current tuning mechanisms within the three section Fabry-Perot resonator semiconductor laser using three coupled Fabry-Perot cavities. The two section current tuning mechanisms provide a much faster tuning ability compared to MEMS or external cavity tunable lasers. Three-section laser diodes provide precise single mode tuning capability but with a gap in the wavelength range. The measured line width of tested samples of the disclosed device is found to be below 1 MHz, while a wavelength stitching method can be used to cover the whole tuning range of 120 nm of the tuning spectrum of a C3 broadly tunable multiple quantum well (MQW) InGaAsP/AnP device.

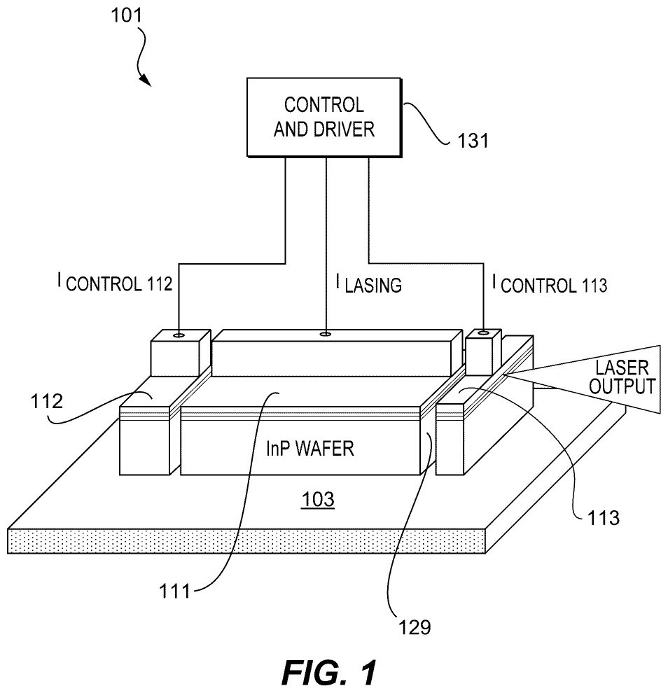

FIG. 1 is a schematic diagram showing a cleaved coupled cavity three-section laser device 101 to implement the disclosed techniques. Laser device 101 is constructed as a tunable cleaved coupled cavity (C3) laser diode using an uncoated Fabry-Pérot resonator. The depicted laser device 101 and its dimensions are given as a non-limiting example.

Depicted are sub-mount 103 and three sections 111, 112, 113, separated by air gaps 121, 122. Laser device 101 used in this example has three sections, that include lasing section 111 between two control sections 112, 113. Sections 111, 112, 113 are separated by air gaps 121, 122 of ˜1.5 μm each. The lengths of sections 111, 112, 113 are 1000 μm (center section 111), 250 μm (end section 112) and 150 μm (end section 113). Light exits from output facet 129 of section 111, which is considered to be the lasing section, with the shorter sections 112, 113 functioning as control sections. The air gap facets are kept at <4° for optimum coupling of light from the three sections 111, 112, 113. The laser structure is a wide gain profile structure of asymmetric multiple quantum well (AMQW) structure. Also depicted is a control circuit and driver 131, which provides current to sections 111, 112, 113.

The longitudinal modes of the coupled cavity laser device 101 are the ones that are common to sections 111, 112, 113. The enforced lasing mode of laser device 101 is the one that possesses the highest gain. Sections 111, 112, 113 are provided with lasing current I_{lasing} and I_{control 112} and I_{control 113} by control circuit and driver 131. By varying the injection current in either or all sections 111, 112, 113, the refractive index of the individual sections 111, 112, 113 can be changed or adjusted, which in turn changes the longitudinal mode spacing of the laser device 101. This allows a new mode to be lined up against the gain peak of the active region material. Various combinations of lasing currents and control currents provide lasing in different longitudinal modes of the laser device 101.

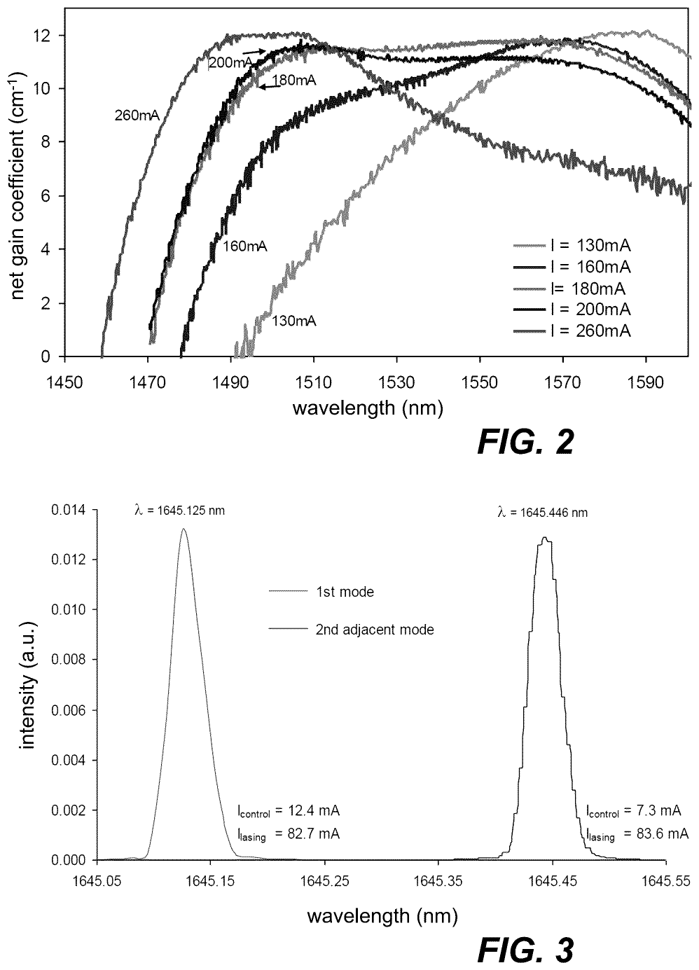

FIG. 2 is a graphic depiction showing a net gain coefficient found from the spectrum measured by an optical spectrum analyzer (OSA) at different current injection levels, which shows the measured gain profile for this AMQW laser. The broad tunability is associated with the broad gain profile of the asymmetric multiple quantum wells (AMQW) used in the active region of the C3 laser diode device. The AMQW laser structure used in this non-limiting example has five quantum wells (QWs) that produce the broad net gain profile. These QWs have room temperature PL peaks at 1.599, 1.458, 1.430, 1.430 and 1.599 μm from the p-side to the n-side. The AMQWs come either in different widths or compositions where each well has a different gain profile. The barrier and the well widths are designed so that a coupling exists among the wells. The coupling helps to ensure that all wells are pumped; however, the wells contribute individually and hence a broad gain profile is achieved. This increases the spectral width over which lasing can be obtained.

FIG. 3 is a graphic depiction showing an OSA-measured spectrum for a continuous tuning method. The spectrum is generated by a C3 laser diode device with two adjacent modes at different I_{lasing} and I_{control 112} ratios. The mode spacing for this C3 laser diode device is 0.321 nm.

The mode spacing of the disclosed C3 laser diode was found, in one study, to be around 0.32 nm; however, it can vary depending on the side wall tilt of the gap between the sections (e.g., sections 111, 112, 113 in FIG. 1). When the injected current in the control sections 112, 113 is fixed at a selected value, the C3 laser diode device will lase at one of these single longitudinal modes. As the injected current varies in the control sections 112, 113, the C3 laser diode device will scan through different modes in a discrete manner. FIG. 3 shows two adjacent modes at different I_{lasing} and I_{control 112} ratios. I_{control 113} is set to 0 mA at this point.

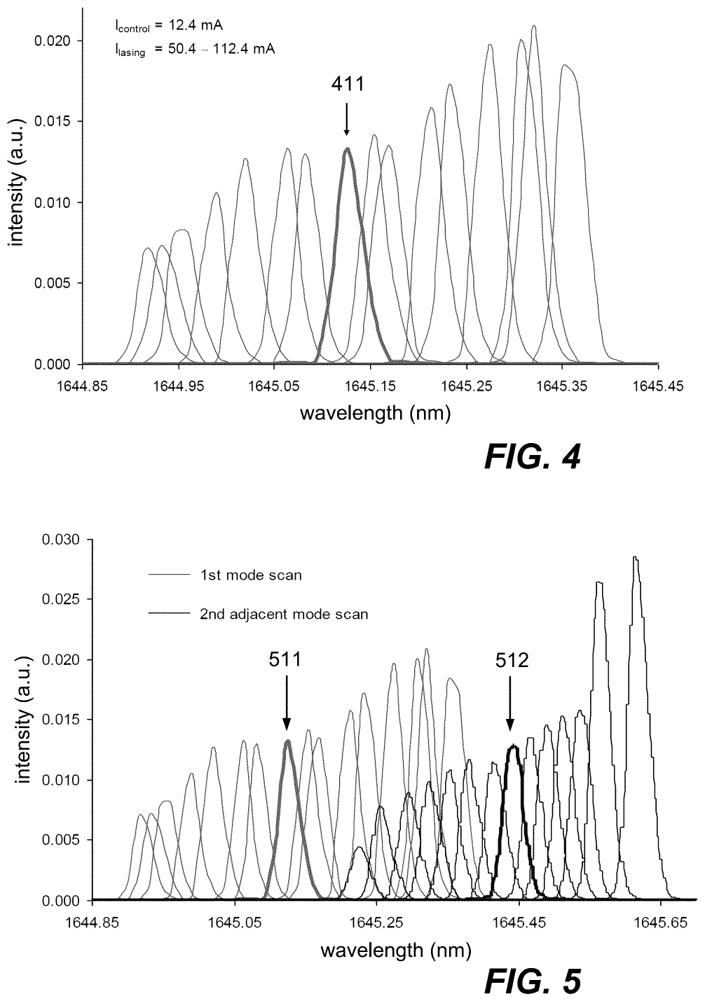

FIG. 4 is a graphic depiction showing tuning of a single mode, as I_{lasing} varies between 50.4-112.4 mA. The thick line curve 411 represents the original mode that was shifted around. The graphs show that the C3 diode laser operates at discrete wavelengths. To have continuous wavelength tuning, the wavelength gap between both adjacent modes needs to be filled. One way to do that is by fixing I_{control} to a selected value and varying I_{lasing}. I_{lasing} can be varied from the lasing threshold to 200 mA. After 200 mA the C3 laser diode device starts to be unstable and mode hoping can occur.

FIG. 5 is a graphic depiction showing the tuning of a single mode as I_{lasing} varies (I_{lasing}=50.4-112.4 mA). The thick line marked with the arrow represents the original mode that was tuned. The resolution of the shift in the wavelength depends on the resolution of the power supply used. With a power supply having high resolution power control, the C3 device will act as a continuous tuning device throughout the whole range, as shown in FIG. 5.

The concept of achieving continuous tuning of the C3 device according to the disclosed technique is to scan the device wavelength around every single mode that the C3 device lases on, as in FIG. 5. The range of the wavelengths scanned is expected to overlap with the adjacent mode scan. This can be achieved by fixing I_{control 112} and I_{control 113} at selected values that give one single mode then scan I_{lasing} such that the wavelength range covers more than the separation between the two adjacent modes. This is followed by changing I_{control 112} and I_{control 113} to lase on the next adjacent mode and then scan biasing to tune to the next mode, as in the previous step. FIG. 5 shows the results of this method where both single modes are shown in FIG. 3 were current tuned and overlapped in the middle. The thick lines 511, 512 in FIG. 5 represent the original modes as shown in FIG. 4.

Since C3 modes tend to be unstable and mode hoping starts to occur if the current is pushed way farther than 200 mA, then to get around that the current needs to be set back slightly above threshold by selecting the mode using I_{control 112}, I_{lasing}, then scanning the range around the mode can be done. An attempt to change both I_{control 112}, and I_{lasing} simultaneously in different ratios resulted in shorter range of tuning and mode hoping occurrence. It has been found that the best practice is to change I_{control 112} close to the end of the range of each I_{lasing} scan, as this allows the range of scan for each mode to be expanded to its maximum.

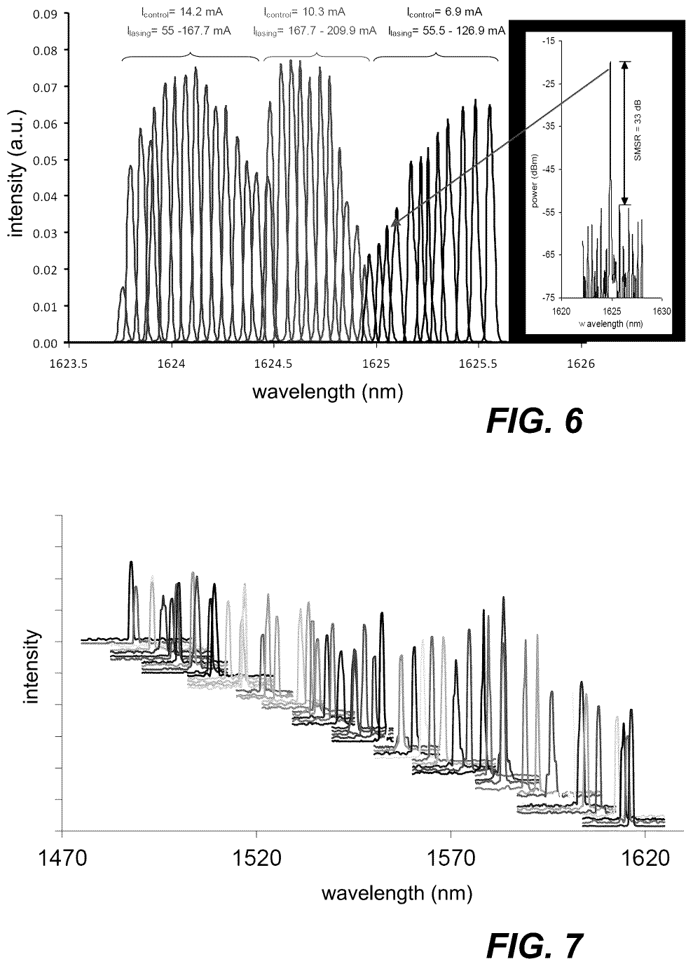

FIG. 6 is a graphic depiction showing the effect of changing both currents on the output of the C3 laser. The insert in the right side shows the SMSR of one of the weak modes marked by the arrow which was ˜33 dBm. I_{control 113} is fixed at 2 mA. This shows the effect of changing the different currents on the output of the C3 laser. The blue scan grouping (left) in FIG. 6 shows the tuning of the mode merely ˜0.7 nm when fixing I_{control 112} to 14.2 mA, I_{control 113} to 2 mA and scanning I_{lasing} in the range 55-167.7 mA. The laser starts to lose its single mode operation after 167.7 mA, but a slight change in I_{control 112} to 10.3 mA expanded the tuning range to ˜1.25 nm as seen in the left grouping (blue) and middle grouping (red) scans. The next step was to select the next adjacent mode by changing I_{control 112} from 14.2 mA to 6.9 mA, I_{lasing} was scanned in the range 55.5-126.9 mA to expand the tuning range to 1.85 nm. The insert in the right side of FIG. 6 shows the SMSR of one of the week modes, marked by the arrow, which was ˜33 dBm.

The overlap of the different scans is used in the reconstruction of the continuous tuning of the full device range. The continuous tuning of the whole range window of 100 nm is a matter of stitching the various scans from each mode together. It is obvious that by changing I_{lasing} the device optical power change which is clearly seen in FIGS. 5 and 6. This change in the optical power needs to be taken into account by normalizing the output optical power.

FIG. 7 is a graphic depiction showing the spectrum range of these wafers that can be obtained by changing I_{control 112}, I_{control 113} and I_{lasing}. The figure did not show all possible modes available, in order to make the figure clear and not crowded for convenience of viewing.

It will be understood that many additional changes in the details, materials, steps and arrangement of parts, which have been herein described and illustrated to explain the nature of the subject matter, may be made by those skilled in the art within the principle and scope of the invention as expressed in the appended claims.

1. A continuously electronically tunable semiconductor laser comprising:
a lasing section;
first and second control sections separated from the lasing section by air gaps in a longitudinal arrangement that positions the lasing section between the two control sections, with the longitudinal arrangement corresponding to a lasing direction of the lasing section, thereby placing longitudinal modes of the semiconductor laser in common with the longitudinal arrangement of the sections, and with the longitudinal arrangement of the sections aligned; and
a circuit providing current to each of the first and second control sections and the lasing section, and providing a tuning capability by varying the current provided to each one of the first control section, the second control section and the lasing section,
wherein the lasing section and the first and second control sections form a Fabry-Pérot resonator with a two or three section current tuning mechanism that provides a tunable laser as a wavelength switchable semiconductor laser using the lasing section and the first and second control sections as three coupled Fabry-Pérot cavities, and
wherein mode hoping is prevented by varying a current provided to the first control section towards an end of a range of a scan of the lasing section current.

2. The electronically tunable semiconductor laser of claim 1, wherein the lasing section and the first and second control sections form the Fabry-Pérot resonator as an uncoated Fabry-Pérot resonator using the three coupled Fabry-Pérot cavities, providing a single mode tuning capability.

3. The electronically tunable semiconductor laser of claim 1, wherein the lasing section and the first and second control sections form supported mode overlapping sections on a common substrate, and the lasing section and the first and second control section obtain continuous coverage of a spectral region as a cleaved coupled cavity (C3) laser diode device having asymmetric multiple quantum wells (AMQW) used in the active region of the C3 laser diode device.

4. The electronically tunable semiconductor laser of claim 3, wherein the lasing section and the first and second control sections form the supported mode overlapping section as a multiple quantum well (MQW) InGaAsP/InP laser device.

5. The electronically tunable semiconductor laser of claim 1, wherein the longitudinal arrangement allows a new mode to be lined up against the gain peak of an active region material of each of the sections.

6. The electronically tunable semiconductor laser of claim 1, wherein providing variations in combinations of lasing currents and control currents provides lasing in different longitudinal modes of the laser device.

7. The electronically tunable semiconductor laser of claim 1, wherein the second control section provides lasing outputs at different wavelengths.

8. The electronically tunable semiconductor laser of claim 1, wherein the circuit provides separately controlled control currents for the first control section and the second control and the second control section provides lasing outputs at different wavelengths.

9. The electronically tunable semiconductor laser of claim 1, wherein the circuit provides continuous tuning of lasing outputs to different wavelengths.

10. A method for providing continuously electronically tunable laser energy, the method comprising:
providing a laser diode as a Fabry-Pérot resonator, with a two or three section current tuning mechanism having a lasing section and first and second control sections separated from the lasing section by air gaps in a longitudinal arrangement that positions the lasing section between the two control sections, with the longitudinal arrangement corresponding to a lasing direction of the lasing section, thereby placing longitudinal modes of the semiconductor laser in common with the longitudinal arrangement of the sections, and with the longitudinal arrangement of the sections aligned and using the lasing section and the first and second control sections as three coupled Fabry-Pérot cavities;
providing current to each of the first and second control sections and the lasing section, and providing a tuning capability by varying the current provided to each one of the first control section, the second control section and the lasing section, and
preventing mode hopping by varying the current provided to the first control section towards an end of a range of a scan of the lasing section current.

11. The method of claim 10, wherein the lasing section and the first and second control sections provide the Fabry-Pérot resonator as an uncoated Fabry-Pérot resonator using the three coupled Fabry-Pérot cavities, providing a single mode tuning capability.

12. The method of claim 10, wherein the lasing section and the first and second control sections obtain continuous coverage of a spectral region as a cleaved coupled cavity (C3) laser diode device having asymmetric multiple quantum wells (AMQW) used in the active region of the C3 laser diode device.

13. The method of claim 10, wherein providing variations in combinations of lasing currents and control currents provides lasing in different longitudinal modes of the laser device.

14. The method of claim 10, wherein providing variations in combinations of lasing currents and control currents provides lasing in different longitudinal modes of the laser device, thereby providing lasing outputs at different wavelengths.

15. The method of claim 10, wherein providing variations in combinations of lasing currents comprises providing separately controlled control currents for the first control section and the second control section to provide lasing in different longitudinal modes of the laser device, thereby providing lasing outputs at different wavelengths.

16. The method of claim 10, wherein providing variations in combinations of lasing currents and control currents provides lasing in different longitudinal modes of the laser device, thereby providing continuous tuning of lasing outputs to different wavelengths.

17. A continuously electronically tunable semiconductor laser comprising:
means for providing a laser diode as a Fabry-Pérot resonator, with a two or three section current tuning mechanism having a lasing section and first and second control sections separated from the lasing section by air gaps in a longitudinal arrangement that positions the lasing section between the two control sections, with the longitudinal arrangement corresponding to a lasing direction of the lasing section, thereby placing longitudinal modes of the semiconductor laser in common with the longitudinal arrangement of the sections, and with the longitudinal arrangement of the sections aligned and using the lasing section and the first and second control sections as three coupled Fabry-Pérot cavities; and
means for providing current to each of the first and second control sections and the lasing section, and providing a tuning capability by varying the current provided to each one of the first control section, the second control section and the lasing section, and
means for preventing mode hopping by varying a current provided to the first control section towards an end of a range of a scan of the lasing section current.
